(19) United States
(12) Patent Application Publication
(10) Pub. No.: US 2026/0335904 A1
(43) Pub. Date: Oct. 29, 2026

(54) DIELECTROPHORETIC AIR FILTER, AIR FILTRATION APPARATUS INCLUDING THE SAME, AND DESIGN METHOD OF DIELECTROPHORETIC AIR FILTER

(71) Applicant: SAMSUNG ELECTRONICS CO., LTD., Suwon-si (KR)

(72) Inventors: Sehyeong Oh, Suwon-si (KR); Jaejun CHANG, Suwon-si (KR); Joonseon JEONG, Suwon-si (KR)

(21) Appl. No.: 19/355,241

(22) Filed: Oct. 10, 2025

(30) Foreign Application Priority Data
Apr. 22, 2025 (KR) 10-2025-0052433
May 21, 2025 (KR) 10-2025-0066096

(51) Int. Cl. B03C 3/08; B03C 3/47; G06F 30/28

(52) U.S. Cl. CPC B03C 3/08; B03C 3/47; G06F 30/28

(57) ABSTRACT

A dielectrophoretic air filter includes: a plurality of parallel plates, which are stacked in a first direction and are made of a dielectric material, and a plurality of electrodes, which extend in a second direction inside each parallel plate of the plurality of parallel plates and are arranged in a third direction. A width of each electrode of the plurality of electrodes is 0.45 to 0.77 mm, a gap between two adjacent electrodes among the plurality of electrodes is 0.63 to 0.90 mm, and a magnitude of a voltage applied to each electrode is 6.3 to 8.8 kV.

### CROSS-REFERENCE TO RELATED APPLICATION

This application claims priority to Korean Patent Application No. 10-2025-0052433, filed on Apr. 22, 2025, and Korean Patent Application No. 10-2025-0066096 filed on May 21, 2025, and all the benefits accruing therefrom under 35 U.S.C. § 119, the contents of which in their entirety are herein incorporated by reference.

### BACKGROUND

### (a) Field

The present disclosure relates to a dielectrophoretic air filter, an air filtration apparatus including the same, and a design method of a dielectrophoretic air filter.

### (b) Description of the Related Art

To improve an air quality in a space, a filter is used to collect particles (e.g., dust) suspended in the air. A high-efficiency particulate air (HEPA) filter has very excellent dust collection performance, but due to its high pressure drop, a large amount of energy is required to create an airflow through the filter. On the other hand, in the case of an electrostatic precipitation method using electrostatic force, a low pressure drop occurs because there are no large obstacles inside the precipitator, but a separate device is used in front of the electrostatic precipitator to charge the particles in order to generate the electrostatic force. However, this device has the disadvantage of generating ozone while charging the particles. A dielectrophoretic air filter is similar to the electrostatic precipitator in that it generates an electric field inside the filter, but it is different in that it can capture even electrically neutral particles by using a dielectrophoretic force instead of the electrostatic force. The dielectrophoretic air filter is attracting attention as an environmentally friendly collection method because it does not require a separate device for charging the particles and thus does not generate ozone.

The dielectrophoretic force is a force that acts on a dipole moment existing in a non-uniform electric field. When a neutral particle exists in the non-uniform electric field, the dipole moment is induced within the particle, so a dielectrophoretic force is applied even though the particle is electrically neutral. To improve the collection performance of the dielectrophoretic air filter, a non-uniform electric field inside the filter can be effectively generated. Because the electric field inside the filter changes depending on design parameters of the filter, it is desirable to predict the performance of the filter according to the filter design parameters well. In addition, when a high voltage is applied, an air discharge may occur in the filter, and in this case, ozone may be generated, so it is desirable to predict the maximum electric field strength inside the filter so that a discharge does not occur.

### SUMMARY

Some embodiments may provide a dielectrophoretic air filter, an air filtration apparatus including the same, and a design method of a dielectrophoretic air filter, for optimizing design parameters that determine performance.

A dielectrophoretic air filter according to an embodiment includes a plurality of parallel plates that are stacked in a first direction and are made of a dielectric material, and a plurality of electrodes that extend in a second direction inside each parallel plate and are arranged in a third direction. A width of each electrode is 0.45 to 0.77 millimeters (mm), a gap between two adjacent electrodes among the plurality of electrodes is 0.63 to 0.90 mm, and a magnitude of a voltage applied to each electrode is 6.3 to 8.8 kilovolts (kV).

In some embodiments, a relative permittivity of the dielectric material may be 2.7 to 3.3, and a half of a thickness of each parallel plate may be 0.13 to 0.19 mm.

In some embodiments, a half of a gap between two adjacent parallel plates among the plurality of parallel plates may be 0.46 to 0.73 mm, and a length of each parallel plate may be 109 to 326 mm.

In some embodiments, a filtration efficiency of the dielectrophoretic air filter may be 95% or more, and a pressure drop of the dielectrophoretic air filter may be 50 pascals (Pa) or less.

In some embodiments, a maximum electric field strength in a space between two adjacent parallel plates among the plurality of parallel plates may be 1.9×10⁷ volts per meter (V/m) or less.

In some embodiments, first voltages of opposite polarities may be applied to the two adjacent electrodes among the plurality of electrodes, and second voltages of opposite polarities may be applied to two electrodes facing each other in two adjacent parallel plates among the plurality of parallel plates.

In some embodiments, the first direction, the second direction, and the third direction may be substantially orthogonal to each other.

In some embodiments, an air filtration apparatus including the dielectrophoretic air filter may be provided.

A dielectrophoretic air filter according to another embodiment may include a plurality of parallel plates that are stacked in a first direction and are made of a dielectric material, and a plurality of electrodes that extend in a second direction inside each parallel plate and are arranged in a third direction. A width of each electrode may be 0.84 mm, a gap between two adjacent electrodes among the plurality of electrodes may be 0.71 mm, and a magnitude of a voltage applied to each electrode may be 10 kV.

In some embodiments, a relative permittivity of the dielectric material may be 3.57, and a half of a thickness of each parallel plate may be 0.27 mm.

According to yet another embodiment, a design method, performed by a computing device, of a dielectrophoretic air filter including a plurality of parallel plates made of a dielectric material and a plurality of electrodes arranged inside each parallel plate is provided. The method includes setting a plurality of design parameters among a plurality of parameters that determine performance of the dielectrophoretic air filter; and determining optimized values of the plurality of design parameters by performing an optimization algorithm that optimizes the performance of the dielectrophoretic air filter.

In some embodiments, the performance may include a filtration efficiency of the dielectrophoretic air filter.

In some embodiments, the optimization algorithm may optimize an objective function defined based on the filtration efficiency.

In some embodiments, the objective function may have a maximum electric field strength in a space between two adjacent parallel plates among the plurality of parallel plates as a constraint.

In some embodiments, the plurality of design parameters may include at least one of a width of each electrode, a gap between two adjacent electrodes among the plurality of electrodes, a magnitude of a voltage applied to each electrode, a relative permittivity of the dielectric material, or a thickness of each parallel plate.

In some embodiments, the performance may further include a pressure drop of the dielectrophoretic air filter.

In some embodiments, the optimization algorithm may be a multi-objective optimization algorithm, and the multi-objective optimization algorithm may optimize a first objective function defined based on the filtration efficiency and a second objective function defined based on the pressure drop.

In some embodiments, the first objective function and the second objective function may have a maximum electric field strength in a space between two adjacent parallel plates among the plurality of parallel plates as a constraint.

In some embodiments, the plurality of design parameters may include at least one of a width of each electrode, a gap between two adjacent electrodes among the plurality of electrodes, a magnitude of a voltage applied to each electrode, a relative permittivity of the dielectric material, a thickness of each parallel plate, a length of each parallel plate, or a gap between two adjacent parallel plates among the plurality of parallel plates.

In some embodiments, the determining the optimized values may include calculating the filtration efficiency by simulating a behavior of particles in the dielectrophoretic air filter.

In some embodiments, the simulating the behavior may include calculating, based on a relationship among an aerodynamic drag force, a dielectrophoretic force, a gravitational force and a velocity of a target particle in the dielectrophoretic air filter, the velocity; updating a position of the target particle based on the velocity; determining whether the target particle has been captured by the dielectrophoretic air filter or has penetrated the dielectrophoretic air filter, based on the updated position of the target particle; updating a number of particles captured by the dielectrophoretic air filter and a number of particles having penetrated the dielectrophoretic air filter among a plurality of particles input to the dielectrophoretic air filter; and calculating the filtration efficiency based on a total number of particles and the number of particles captured by the dielectrophoretic air filter.

### BRIEF DESCRIPTION OF DRAWINGS

FIG. 1 is a diagram illustrating a dielectrophoretic air filter according to an embodiment.

FIG. 2 is a diagram illustrating two parallel plates of a dielectrophoretic air filter according to an embodiment.

FIG. 3 is a diagram explaining parameters of a dielectrophoretic air filter according to an embodiment.

FIG. 4 is a diagram illustrating two adjacent parallel plates and two adjacent electrodes in a dielectrophoretic air filter according to an embodiment.

FIG. 5 is a diagram illustrating a computational domain in a dielectrophoretic air filter according to an embodiment.

FIG. 6 is a diagram illustrating an electric field distribution in a dielectrophoretic air filter according to an embodiment.

FIG. 7 is a diagram illustrating a dielectrophoretic force distribution in a dielectrophoretic air filter according to an embodiment.

FIG. 8 is a flowchart illustrating a method of simulating performance of a dielectrophoretic air filter according to an embodiment.

FIG. 9 is a flowchart illustrating a design method of a dielectrophoretic air filter according to an embodiment.

FIG. 10, FIG. 11, FIG. 12, and FIG. 13 are diagrams illustrating an optimization process in an optimization algorithm according to an embodiment.

FIG. 14 is a flowchart illustrating a design method of a dielectrophoretic air filter according to an embodiment.

FIG. 15 is a diagram illustrating an optimization process in an optimization algorithm according to an embodiment.

FIG. 16 is a diagram illustrating an optimization of a half gap of a parallel plate in an optimization algorithm according to an embodiment.

FIG. 17 is a diagram illustrating an optimization of a length of a parallel plate in an optimization algorithm according to an embodiment.

FIG. 18 is a diagram illustrating an optimization of a half thickness of a dielectric material in an optimization algorithm according to an embodiment.

FIG. 19 is a diagram illustrating an optimization of a relative permittivity of a dielectric material in an optimization algorithm according to an embodiment.

FIG. 20 is a diagram illustrating an optimization of a width of an electrode in an optimization algorithm according to an embodiment.

FIG. 21 is a diagram illustrating an optimization of a gap of an electrode in an optimization algorithm according to an embodiment.

FIG. 22 is a diagram illustrating an optimization of an applied voltage in an optimization algorithm according to an embodiment.

FIG. 23 is a block diagram illustrating an air filtration apparatus according to an embodiment.

### DETAILED DESCRIPTION

In the following detailed description, only certain embodiments of the disclosure have been shown and described, simply by way of illustration. These embodiments are example embodiments. As those skilled in the art would realize, the described embodiments may be modified in various different ways, all without departing from the spirit or scope of the disclosure.

Accordingly, the drawings and description are to be regarded as illustrative in nature and not restrictive. Like reference numerals designate like elements throughout the specification. The sequence of operations or steps is not limited to the order presented in the claims or figures unless specifically indicated otherwise. The order of operations or steps may be changed, several operations or steps may be merged, a certain operation or step may be divided, and a specific operation or step may not be performed.

As used herein, the singular forms “a” and “an” are intended to include the plural forms as well, unless the context clearly indicates otherwise. Although the terms first, second, and the like may be used herein to describe various elements, components, steps, and/or operations, these terms are only used to distinguish one element, component, step, or operation from another element, component, step, or operation.

Further, “and/or” includes each of elements, components, steps, and/or operations mentioned and any combination of one or more of them. “About” or “substantially orthogonal” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially orthogonal” can mean within one or more standard deviations, or within ±10 degrees) (°), 5° or 2° of the stated value.

Furthermore, the terms including ordinal numbers such as “first”, “second”, etc. may be used to describe various elements, components, steps, and/or operations, but the elements, components, steps, and/or operations are not limited by the terms. The terms are used only for the purpose of distinguishing one element, component, step, or operation from another element, component, step, or operation. For example, without departing from the range of the technology disclosed in this specification, a first element, component, step, or operation may be named a second element, component, step, or operation, and similarly, a second element, component, step, or operation may be named a first element, component, step, or operation.

Additionally, when a part of a layer, membrane, region, or plate is said to be “above” or “on” another part, this includes not only cases where it is “directly above” another part, but also cases where there is another part in-between. Conversely, when a part is said to be “right on top” or “directly on top” of another part, it means that there is no other part in-between. In the drawings, the thicknesses of each of layers or regions may be enlarged or reduced to clearly various layers or regions.

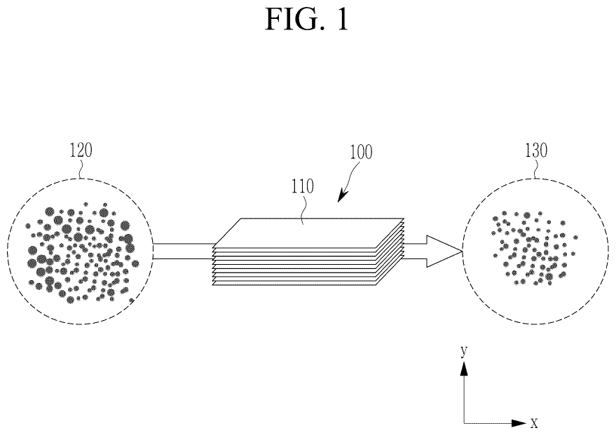

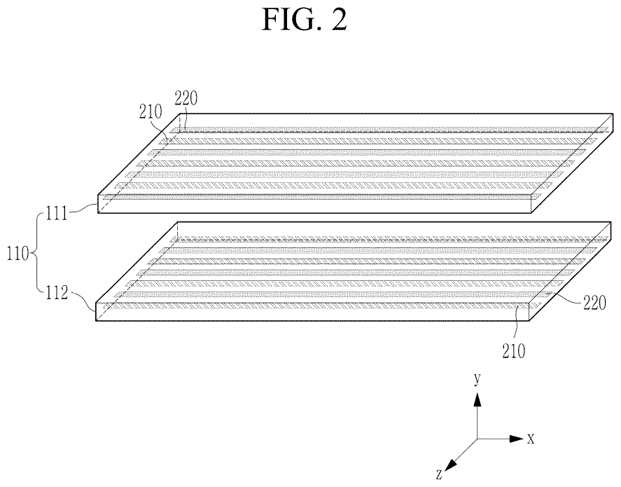

FIG. 1 is a diagram illustrating a dielectrophoretic air filter according to an embodiment, and FIG. 2 is a diagram illustrating two parallel plates of a dielectrophoretic air filter according to an embodiment.

Referring to FIG. 1, a dielectrophoretic air filter 100 may include a plurality of parallel plates 110 stacked with a gap in a first direction (e.g., y-axis direction). The parallel plate 110 may be made of a dielectric material. The plurality of parallel plates 110 may be parallel to each other. In some embodiments, the gap between two adjacent parallel plates 110 among the plurality of parallel plates 110 may be the same.

Referring to FIG. 2, a plurality of electrodes 210 and 220 may be formed inside each parallel plate 110. In some embodiments, the plurality of electrodes 210 and 220 may be located in the middle of a thickness direction (e.g., y-axis direction) of the parallel plate 110. The plurality of electrodes 210 and 220 may extend in a second direction (e.g., x-axis direction) and may be arranged with a gap in a third direction (e.g., z-axis direction). In some embodiments, the gap (alternatively, separation) between two adjacent electrodes 210 and 220 among the plurality of electrodes 210 and 220 may be the same. The first direction, the second direction, and the third direction may be substantially orthogonal to each other.

The plurality of electrodes 210 and 220 include positive electrodes 210 to which a positive voltage is applied and negative electrodes 220 to which a negative voltage is applied, and the positive electrodes 210 and the negative electrodes 220 may be alternately arranged in the third direction. In some embodiments, the plurality of electrodes 210 and 220 may have the same width (e.g., length in the z-axis direction) and the same length (e.g., length in the x-axis direction). Voltages of opposite polarities may be applied to two facing electrodes 210 and 220 in two adjacent parallel plates 111 and 112. The positive electrode 210 of an upper parallel plate 111 may face the negative electrode 220 of a lower parallel plate 112, and the negative electrode 220 of the upper parallel plate 111 may face the positive electrode 210 of the lower parallel plate 112.

Referring to FIG. 1 and FIG. 2, air 120 including particles may flow between the parallel plates 110 (e.g., may flow in the x-axis direction between the parallel plates 110). The particles in the air 120 flowing into the parallel plates 110 may be electrically neutral. A non-uniform electric field may be induced between the parallel plates 110 by the electrodes 210 and 220 located on the parallel plates 110. As the particles pass through the electric field between the parallel plates 110, they may receive a dielectrophoretic force to be captured on the surface of the parallel plates 110. Therefore, the dielectrophoretic air filter 100 may operate as an air filter that captures particles from the incoming air 120 and outputs air 130 from which the particles have been filtered.

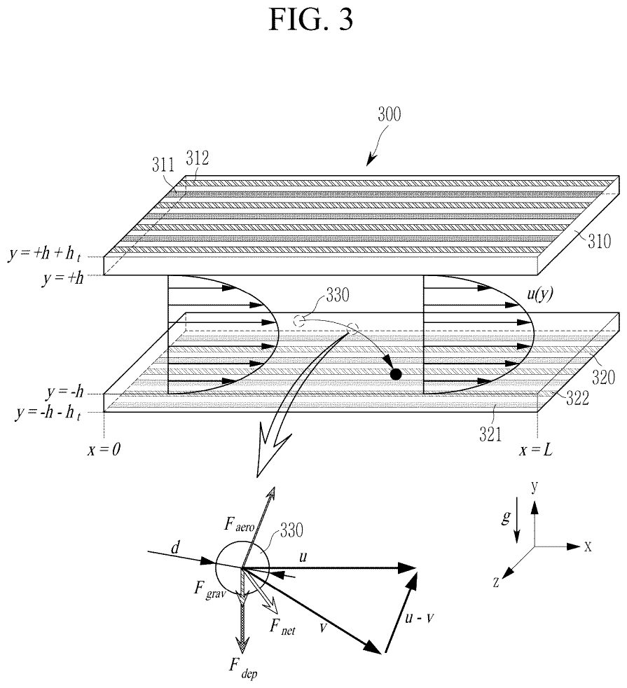

Next, parameters affecting performance of a dielectrophoretic air filter are described with reference to FIGS. 3 to 7.

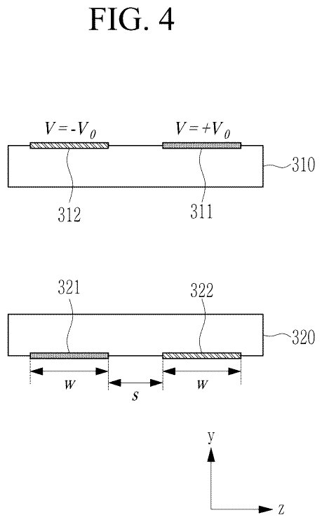

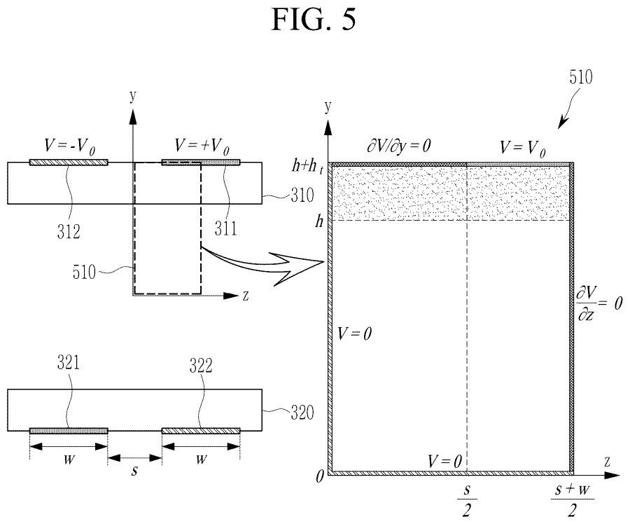

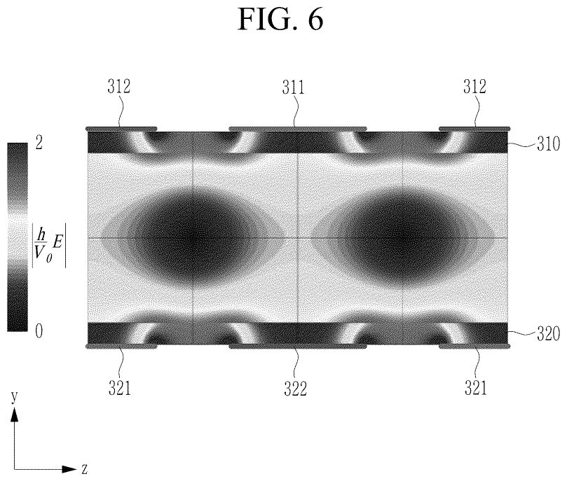

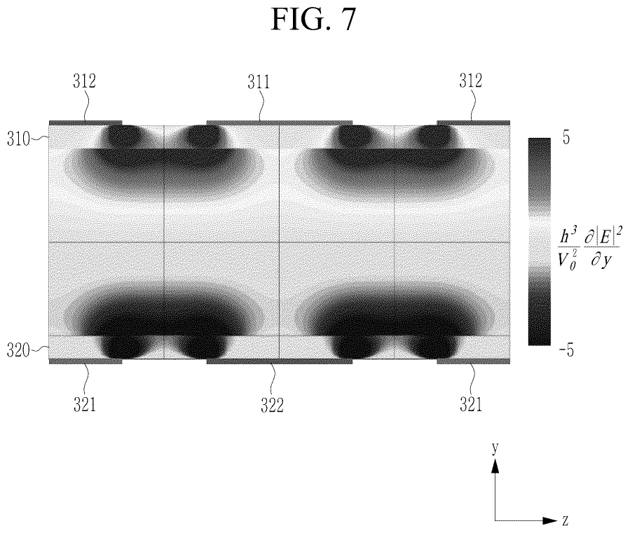

FIG. 3 is a diagram explaining parameters of a dielectrophoretic air filter according to an embodiment, FIG. 4 is a diagram illustrating two adjacent parallel plates and two adjacent electrodes in a dielectrophoretic air filter according to an embodiment, FIG. 5 is a diagram illustrating a computational domain in a dielectrophoretic air filter according to an embodiment, FIG. 6 is a diagram illustrating an electric field distribution in a dielectrophoretic air filter according to an embodiment, and FIG. 7 is a diagram illustrating a dielectrophoretic force distribution in a dielectrophoretic air filter according to an embodiment.

For convenience, two adjacent parallel plates 310 and 320 among a plurality of parallel plates of a dielectrophoretic air filter 300 are shown in FIG. 3, and two electrodes 311 and 312 of the parallel plate 310 and two electrodes 321 and 322 of the parallel plate 320 facing the two electrodes 311 and 321 are shown in FIGS. 4 to 7. In addition, in FIGS. 3 to 7, only a portion corresponding to a half in a thickness direction of each of the parallel plates 310 and 320 is shown for convenience.

Referring to FIG. 3 and FIG. 4, the two parallel plates 310 and 320 may be separated by a gap of 2h. If a y-axis coordinate of a center of the two parallel plates 310 and 320 in the y-axis direction is 0, a y-axis coordinate of a bottom surface of the parallel plate 310 may be given as +h, and a y-axis coordinate of a top surface of the parallel plate 320 may be given as −h. If a thickness (e.g., length in the y-axis direction) of the parallel plate 310 or 320 is 2 hₜ, a y-axis coordinate of the electrodes 311 and 312 located in a center of the parallel plate 310 may be given as +h+hₜ, and a y-axis coordinate of the electrodes 321 and 322 of the parallel plate 320 may be given as −h−hₜ. If a length (e.g., length in the x-axis direction) of the parallel plate 310 or 320 is L, and an x-axis coordinate of one end (e.g., left end in FIG. 3) of the parallel plate 310 or 320 in the x-axis direction is 0, an x-axis coordinate of the other end (e.g., right end in FIG. 3) of the parallel plate 310 or 320 in the x-axis direction may be given as L.

The positive electrode 311 of the parallel plate 310 and the negative electrode 322 of the parallel plate 320 may face each other, and the negative electrode 312 of the parallel plate 310 and the positive electrode 321 of the parallel plate 320 may face each other. A voltage having the same magnitude is applied to the positive electrodes 311 and 321 and the negative electrodes 312 and 322, and a voltage of +V₀ may be applied to the positive electrodes 311 and 321, and a voltage of −V₀ may be applied to the negative electrodes 312 and 322. A gap (alternatively, separation) between two electrodes 311 and 312 or 321 and 322 may be s, and a width (e.g., length in the z-axis direction) of each electrode 311, 312, 321, or 322 may be w.

Designable design parameters in the dielectrophoretic air filter 300 may include at least one of the gap 2 h between the two parallel plates 310, 320, a length L in a flow direction (e.g., x-axis direction) of the parallel plates 310 and 320, a flow velocity (alternatively, velocity of airflow) u in a horizontal direction (e.g., x-axis direction) between the parallel plates 310 and 320, the thickness (e.g., length in the y-axis direction) hₜ of the parallel plate 310 or 320, a relative permittivity ε_{r,m} of the dielectric material of the parallel plates 310 and 320, the width w of each electrode 311, 312, 321, or 322, the gap s between the positive electrode 311 or 321 and the negative electrode 312 or 322, or the magnitude V₀ of the applied voltage. The collection performance of the dielectrophoretic air filter 300 may be determined based on the design parameters. The collection performance of the dielectrophoretic air filter 300 may be determined based on particle parameters related to the characteristics of a particle 330, in addition to the design parameters. The particle parameters may include at least one of a particle density ρₚ, a particle relative permittivity ε_{r,p}, or an effective diameter d of the particle.

The particle 330 inflowing between the parallel plates 310 and 320 may be subjected to an aerodynamic drag force Fₐₑᵣₒ due to an airflow, a dielectrophoretic force F_{dep}, and a gravitational force F_{grav}. The behavior of the particle 330 may be determined by a sum Fₙₑₜ of these forces and may be given as in Equation 1.

$${m}_{p} \frac{dv}{dt} = {F}_{aero} + {F}_{dep} + {F}_{grav} \qquad Equation 1$$

In Equation 1, mₚ denotes a mass of the particle 330 and may be given as βₚπd³/6, v denotes a velocity of the particle 330, and t denotes time.

When the velocity of the airflow (air flow) at a current position of the particle 330 is u, a relative velocity of the airflow with respect to the particle 330 is u-v. Because the aerodynamic drag force Fₐₑᵣₒ due to the airflow acts in the direction of the relative velocity u-v, the aerodynamic drag force Fₐₑᵣₒ may be given as in Equation 2.

$${F}_{a e r o} = \frac{\frac{1}{2} {ρ}_{f} {C}_{D} ( \frac{π {d}^{2}}{4} ) \vert u - v \vert ( u - v )}{{C}_{c}} \qquad Equation 2$$

In Equation 2, ρ_{f} denotes a density of air, C_{D} denotes a drag coefficient, and C_{C} denotes a Stokes-Cunningham factor. The density of air pr may be 1.2 kilograms per cubic meter (kg/m³), the drag coefficient C_{D} may be given as in Equation 3, and the Stokes-Cunningham factor C_{C} may be given as in Equation 5.

$${C}_{D} = \frac{24}{R {e}_{p}} ( 1 + 0.15 R {e}_{p}^{0.687} ) for {Re}_{p} < 1000 \qquad Equation 3$$

In Equation 3, Reₚ denotes a Reynolds number of the particle 330, and may be given as in Equation 4.

$$R {e}_{p} = \frac{{ρ}_{f} d \vert u - v \vert}{μ} \qquad Equation 4$$

In Equation 4, μ denotes a viscosity of air and may be given as 1.8×10⁻⁵ kg/ms.

$${C}_{c} = 1 + \frac{2 λ}{d} ( 1.257 + 0.4 {e}^{- ( \frac{1.1 d}{2 λ} ) )} \qquad Equation 5$$

In Equation 5, λ denotes an average free path of air molecules at room temperature and may be 65 nanometers (nm).

In some embodiments, the airflow velocity u between the parallel plates 310 and 320 in Equation 2 may be calculated or measured through a computational fluid dynamics (CFD) simulation or an experiment. However, because the CFD simulation or the experiment takes a very long time, it may not be suitable for an optimization process to quickly predict the performance of a filter according to design parameters. On the other hand, considering an operating flow velocity of a conventional dielectrophoretic air filter and the gap between the parallel plates 310 and 320, a Reynolds number Reₕ of the airflow may be given as in Equation 6, so it can be seen that the airflow between the parallel plates 310 and 320 operates under a laminar flow condition (Reₕ<2000). Therefore, in some embodiments, assuming that the flow between the parallel plates 310 and 320 is a fully-developed laminar flow, the airflow velocity distribution u and a corresponding aerodynamic drag force may be calculated using a theoretical equation such as Equation 7.

$$R {e}_{h} ( = 4 \frac{{ρ}_{f} \overline{u} h}{μ} ) ∼ O ( {10}^{2} ) \qquad Equation 6$$

In Equation 6, ū is a mean flow velocity between the parallel plates 310 and 320.

$$u = u ( y ) {e}_{x} = \frac{3}{2} \overline{u} ( 1 - \frac{{y}^{2}}{{h}^{2}} ) {e}_{x} \qquad Equation 7$$

In Equation 7, eₓ denotes a unit vector in the x-axis direction. Equation 7 may show that the airflow velocity distribution between the parallel plates 310 and 320 has a parabolic shape (a quadratic function of y) as shown in FIG. 3. In the case of the fully developed laminar flow, a pressure drop Δp while passing between the parallel plates 310 and 320 may be predicted as in Equation 8.

$$Δ p = \frac{3 μ \overline{u} L}{{h}^{2}} \qquad Equation 8$$

The dielectrophoretic force F_{dep} applied to the particle 330 in Equation 1 may be calculated as in Equation 9.

$${F}_{d e p} = \frac{1}{4} π {d}^{3} {ε}_{0} {ε}_{r , f} K ∇ {\vert E \vert}^{2} \qquad Equation 9$$

In Equation 9, ε₀ denotes a vacuum permittivity, ε_{r,f} denotes a relative permittivity of air, K denotes a Clausius-Mossotti factor, and E denotes an electric field. The vacuum permittivity ε₀ may be 8.85×10⁻¹² farads per meter (F/m), and the relative permittivity of air ε_{r,f} may be 1.0006. The Clausius-Mossotti factor K may be calculated as (ε_{r,p}−ε_{r,f})/(ε_{r,p}+2ε_{r,f}).

To calculate the dielectrophoretic force F_{dep} through Equation 9, the electric field E between the parallel plates 310 and 320 may be calculated. Because the electrodes 311, 312, 321, and 322 are arranged along the x-axis direction, as shown in FIG. 5, some embodiments may calculate the electric field E by numerically analyzing a governing equation (for example, a Laplace's equation) for an electric potential V on an yz plane (i.e., plane defined by y-axis direction and z-axis direction). FIG. 5 shows a computational domain 510 for a numerical analysis of the Laplace's equation, and shows an example in which a boundary condition of the Laplace's equation is set by considering a symmetry of the electrodes 311, 312, 321, and 322 and a continuous distribution of the electric field E.

As shown in FIG. 5, an intersection of a line in the y-axis direction passing through a center of two adjacent electrodes 311 and 312 or 321 and 322 and a line in the z-axis direction passing through a center of two adjacent parallel plates 310 and 320 on the yz plane may be set as an origin of the computational domain 510. For example, the computational domain 510 may be set from the origin to the center of the parallel plate 310 in the y-axis direction, and to the center of the electrode 311 in the z-axis direction. That is, a rectangle formed by the origin, (h+hₜ, 0), (0, (s+w)/2), and (h+hₜ, (s+w)/2) on the yz plane may be set as the computational domain 400. In this case, a potential V on a straight line between (0, 0) and (0, (s+w)/2) is 0, a potential V on a straight line between (0, 0) and (h+hₜ, 0) is 0, a partial derivative OV/oy of a potential V with respect to y on a straight line between (h+hₜ, 0) and (h+hₜ, s/2) is 0, a potential V on a straight line between (h+hₜ, s/2) and (h+hₜ, (s+w)/2) is V₀, and a partial derivative δV/δz of a potential V with respect to z on a straight line between (h+hₜ, (s+w)/2) and (0, (s+w)/2) is 0, which may be set as the boundary condition.

The Laplace's equation for the potential V such as Equation 10 may be numerically analyzed for the computational domain 510.

$$\frac{\partial }{\partial y} ( {ε}_{r} \frac{\partial V}{\partial y} ) + \frac{\partial }{\partial z} ( {ε}_{r} \frac{\partial V}{\partial z} ) = 0 \qquad Equation 10$$

In Equation 10, εᵣ=ε_{r,f} (0<y<h) and εᵣ=ε_{r,m} (h<y<h+hₜ).

The electric field E of the space between the parallel plates 310 and 320 may be obtained through the relationship of E=−∇V and the potential V obtained through Equation 10.

Finally, the gravitational force F_{grav} acting on the particle 330 is F_{grav}=mₚg, and may be given as in Equation 11.

$${F}_{g r a v} = \frac{{ρ}_{p} π {d}^{3}}{6} g \qquad Equation 11$$

In Equation 11, g denotes a gravitational acceleration.

Through the method described above, the right side of Equation 1, i.e., the aerodynamic drag force Fₐₑᵣₒ, the dielectrophoretic force F_{dep}, and the gravitational force F_{grav} may be calculated. By analyzing an equation of motion such as Equation 12, a velocity v of the particle 330 and a position x=(x,y,z) of the particle 330 over time may be calculated.

$$\{ \begin{matrix}{m}_{p} \frac{dv}{d t} = {F}_{a e r o} + {F}_{d e p} + {F}_{g r a v} \\ \frac{dx}{dt} = v\end{matrix} \qquad Equation 12$$

Table 1 shows an example of design parameters and particle parameters for calculating the electric field E and the behavior of the particle 330 in the dielectrophoretic air filter according to an embodiment. The design parameters may include design parameters related to the parallel plates 310 and 320, design parameters related to the dielectric material of the parallel plates, and/or design parameters related to the electrodes 311, 312, 321, and 322. The parameters related to the parallel plates 310 and 320 may include a mean flow velocity between the parallel plates 310 and 320, a gap (alternatively, height) between the parallel plates 310 and 320, and/or a length of the parallel plates 310 and 320. In the calculation, a half gap (alternatively, half height) between the parallel plates 310 and 320 may be used instead of the gap between the parallel plates 310 and 320. The half gap (the half of the gap) means the half of the physical gap. In some embodiments, because the center of the two adjacent parallel plates 310 and 320 on the yz plane is set as the origin of the computational domain 510 as shown in FIG. 5, a length (i.e., the half gap) between the origin and the parallel plate 310 may be used instead of the full value of the gap. The design parameters related to the dielectric material may include a thickness and/or a relative permittivity of the parallel plates 310 and 320, i.e., the dielectric material. In the calculation, a half thickness of the dielectric material may be used instead of the thickness of the dielectric material. The half thickness (the half of the thickness) means the half of the physical thickness. In some embodiments, because the computational domain 510 is set from the origin to the center of the parallel plate 310 in the y-axis direction, a length (i.e., the half thickness) between the bottom surface of the parallel plate 310 and the center of the parallel plate 310 may be used instead of the full value of the thickness. The design parameters related to the electrodes 311, 312, 321, and 322 may include a width of the electrodes 311, 312, 321, and 322, a gap (alternatively, separation) between the electrodes 311 and 312 or 321 and 322, and/or a magnitude of a voltage applied to the electrodes 311, 312, 321, and 322. The particle parameters may include a density of the particle, a relative permittivity of the particle, and/or an effective diameter of the particle.

Equation 10 may be numerically analyzed by using the parameters provided in Table 1, and the electric field E induced between the parallel plates 310 and 320 may be calculated through the relationship of E=−∇V. The dielectrophoretic force F_{dep} applied to a particle at an arbitrary position may be calculated based on the calculated electric field E and Equation 9. For example, the electric field E and the dielectrophoretic force F_{dep} may be distributed as shown in FIG. 6 and FIG. 7, respectively.

TABLE 1

| Description | | Parameter | Symbol | Value | |
|---|---|---|---|---|---|
| Design | Parallel | Mean | ū | 1 | m/s |
| parameters | plates | velocity | | | |
| | (Channel) | Half gap | h | 0.8 | mm |
| | | (half height) | | | |
| | | Length | L | 200 | mm |
| | Dielectric | Half | hₜ | 0.2 | mm |
| | material | thickness | | | |
| | | Relative | ε_{r,m} | 3.4 | |
| | | permittivity | | | |
| | Electrodes | Width | w | 1.24 | mm |
| | | Gap | s | 0.72 | mm |
| | | (separation) | | | |
| | | Voltage input | V₀ | 8.5 | kV |
| Particle parameters | | Density | ρₚ | 2200 | kg/m³ |
| | | Relative | ε_{r,p} | 6 | |
| | | permittivity | | | |
| | | Diameter | d | 1 | μm |

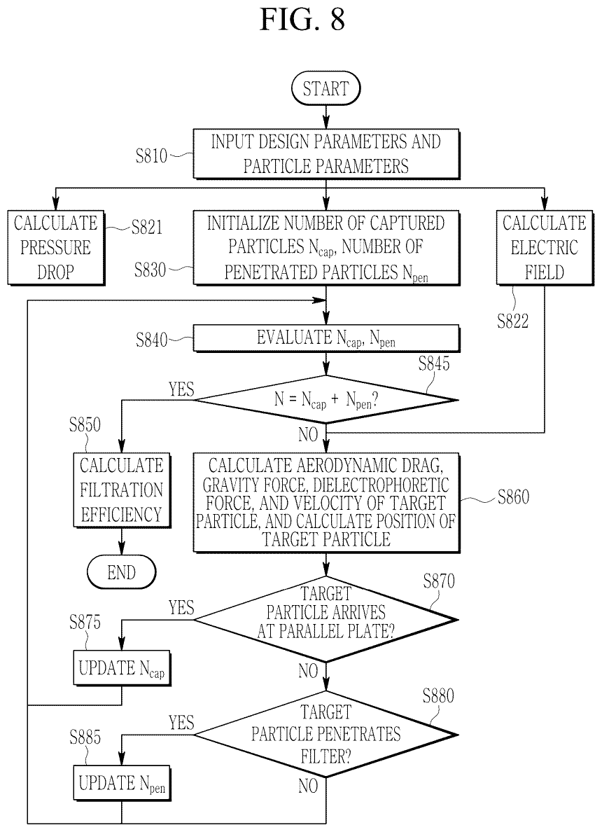

FIG. 8 is a flowchart illustrating a method of simulating performance of a dielectrophoretic air filter according to an embodiment.

Referring to FIG. 8, after uniformly placing a plurality of particles having characteristics corresponding to particle parameters for simulation (e.g., particle parameters shown in Table 1) at an inlet of a dielectrophoretic air filter (e.g., a position where an x coordinate is 0 in FIG. 3), a simulation device may calculate the behavior of the particles. That is, at an initial time of the simulation, the plurality of particles may be uniformly located on an yz plane where the x coordinate is 0.

To calculate the behavior of the particles, the simulation device may input design parameters and particle parameters (S810). Based on design parameters, the particle parameters, and constant values, the simulation device may calculate a pressure drop and an electric field strength of the dielectrophoretic air filter based on Equations 8 and 10, respectively (S821 and S822). The constant values may include, for example, an air parameter, a gravitational acceleration (g=9.81 m/s²), and a vacuum permittivity (ε₀=8.85×10⁻¹² F/m). The air parameter may include a viscosity of air (μ=1.8×10\hat{ }⁵ kilograms per millisecond (kg/ms)), a density of air (ρ_{f}=1.2 kg/m³), and a relative permittivity of air (ε_{r,f}=1.0006).

At a time point (i.e., initial time point) when N particles are uniformly located between parallel plates (e.g., 310 and 320 in FIG. 3) corresponding to the inlet of the dielectrophoretic air filter, the simulation device may initialize the number of particles N_{cap} captured by the dielectrophoretic air filter N_{cap} and the number of particles Nₚₑₙ that have penetrated (or have not been captured by) the dielectrophoretic air filter (S830). For example, the simulation device may set N_{cap} and Nₚₑₙ to zero (S830).

As time elapses (i.e., as the particles pass through the dielectrophoretic air filter), the simulation device may evaluate the number of particles N_{cap} captured by the dielectrophoretic air filter and the number of particles Nₚₑₙ having penetrated the dielectrophoretic air filter (S840). The simulation device may determine whether a sum of the number of particles N_{cap} captured by the dielectrophoretic air filter and the number of particles Nₚₑₙ having penetrated the dielectrophoretic air filter is equal to a total number of particles N (i.e., whether N_{cap}+Nₚₑₙ=N) (S845).

If the sum of the number of particles N_{cap} captured by the dielectrophoretic air filter and the number of particles Nₚₑₙ having penetrated the dielectrophoretic air filter is not equal to the total number of particles N (S845: No), the simulation device may update the positions of some particles (S860). Some particles may be particles excluding the captured particles and the penetrated particles from the total particles, and are referred to as update target particles. The simulation device may calculate an aerodynamic drag force Fₐₑᵣₒ, a dielectrophoretic force F_{dep}, a gravitational force F_{grav}, and a velocity v of each target particle at a current time point (or current position) based on an equation of motion (e.g., Equation 12, and Equations 2, 9, 10, and 11 used in the calculation of Equation 12), and calculate (or update) a position x of the target particle (S860).

When a certain target particle has reached the parallel plate 310 or 320 at the updated position (S870: Yes), the simulation device may update the number of captured particles N_{cap} (S875). The simulation device may update the number of captured particles N_{cap} by increasing the number of captured particles N_{cap} by one (alternatively, adding one to N_{cap}) (S875). In some embodiments, when a y coordinate of the target particle at the updated position satisfies |y|≥h (i.e., when the y coordinate is-h or less or +h or more), the simulation device may determine that the corresponding target particle has reached the parallel plate 310 or 320.

When a certain target particle has penetrated the dielectrophoretic air filter (S880: Yes), the simulation device may update the number of particles Nₚₑₙ having penetrated the dielectrophoretic air filter (S885). The simulation device may update the number of particles Nₚₑₙ having penetrated the dielectrophoretic air filter by increasing the number of particles Nₚₑₙ having penetrated the dielectrophoretic air filter Nₚₑₙ by one (alternatively, adding one to Nₚₑₙ) (S885). The simulation device may determine whether the corresponding target particle has penetrated the dielectrophoretic air filter based on the updated position of the target particle (S880). In some embodiments, when an x coordinate of the updated position of the target particle satisfies x≥L (i.e., when the x coordinate is L or more), the simulation device may determine that the corresponding target particle has penetrated the dielectrophoretic air filter.

The simulation device may repeat the process of updating the position x=(x, y, z) of the target particles, the number of captured particles N_{cap}, and the number of passed particles Nₚₑₙ (S860, S870, S875, S880, and S885) until the sum of the number of particles N_{cap} captured by the dielectrophoretic air filter and the number of particles Nₚₑₙ having penetrated the dielectrophoretic air filter is equal to the total number of particles N (i.e., N_{cap}+Nₚₑₙ=N) (S845).

If the sum of the number of particles captured by the dielectrophoretic air filter N_{cap} and the number of particles Nₚₑₙ having penetrated the dielectrophoretic air filter is equal to the total number of particles N (S845: Yes), the simulation device may calculate a filtration efficiency (S850). In some embodiments, the simulation device may calculate the filtration efficiency n as N_{cap}/N (S850). In this way, the simulation device may evaluate the filtration efficiency by analyzing the behavior of N particles. When the filtration efficiency was evaluated based on the parameters given in Table 1, it was confirmed that it has a filtration efficiency of about 86%.

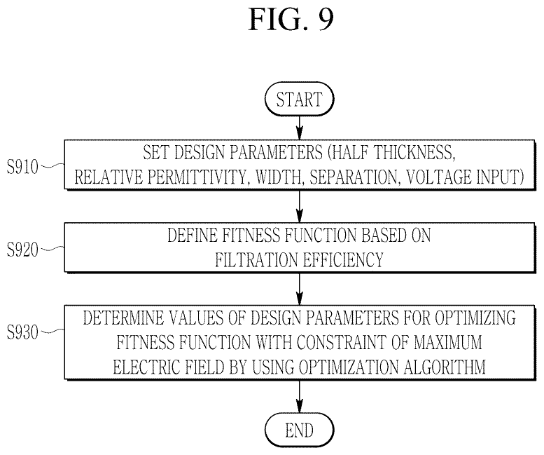

Next, a method of optimizing design parameters of a dielectrophoretic air filter is described with reference to FIGS. 9 to 13.

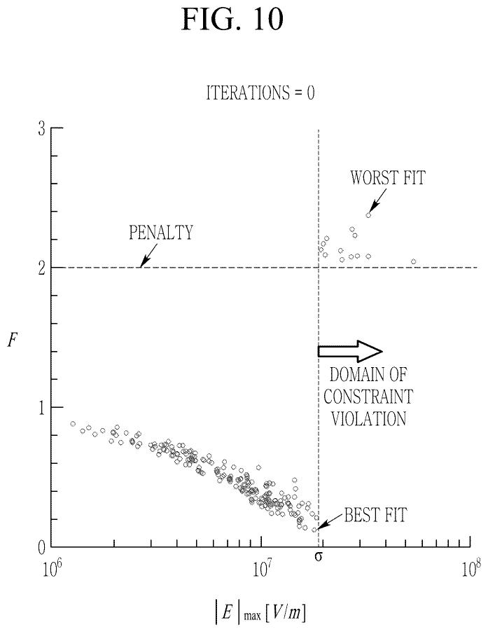

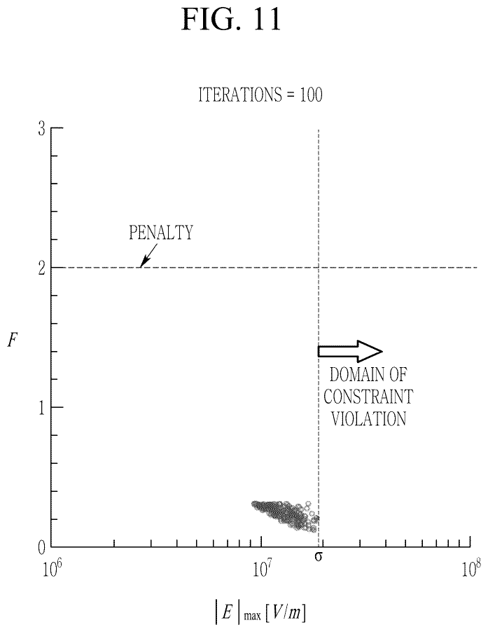

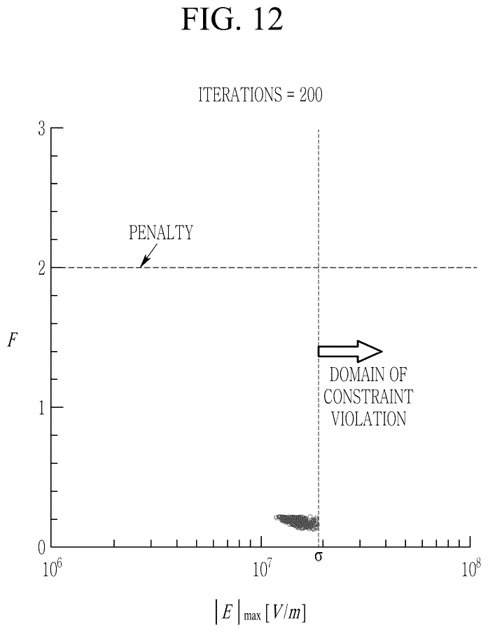

FIG. 9 is a flowchart illustrating a design method of a dielectrophoretic air filter according to an embodiment, and FIG. 10, FIG. 11, FIG. 12, and FIG. 13 are diagrams illustrating an optimization process in an optimization algorithm according to an embodiment.

Referring to FIG. 9, a simulation device may set a plurality of design parameters to be used for optimization among a plurality of parameters that determine performance of a dielectrophoretic air filter (S910). The simulation device may aim to maximize a filtration efficiency in the performance of the dielectrophoretic air filter. In this case, the simulation device may fix design parameters related to the parallel plates (e.g., a mean flow velocity u, a half gap h between parallel plates, a length L of a parallel plate) to fix the pressure drop Δp defined in Equation 8, and may optimize design parameters related to a dielectric material and electrodes (a half thickness hₜ of the dielectric material, a relative permittivity ε_{r,m} of the dielectric material, a width w of the electrode, a gap s between the electrodes, and an applied voltage V₀).

The simulation device may define an objective function for maximizing the filtration efficiency based on the filtration efficiency, which is the performance of the dielectrophoretic air filter to be optimized (S920). In some embodiment, the objective function may be a fitness function. The simulation device may determine optimized values of the design parameters that optimize the objective function by performing an optimization algorithm (S930).

In some embodiments, the simulation device may optimize the design parameters so that a maximum electric field strength |E|ₘₐₓ in a space between the parallel plates is equal to or less than a certain value σ to prevent an air discharge. The certain value σ may be, for example, 1.9×10⁷ V/m. The simulation device may optimize the design parameters through an optimization with an inequality constraint as in Equation 13.

max η(Ξ) subject to |E|ₘₐₓ(Ξ)<σ Equation 13

In Equation 13, Ξ is a set of design parameters to be optimized, and in some embodiments, may be given as in Equation 14.

Ξ=(hₜ,ε_{r,m},w,s,V₀) Equation 14

To solve the problem of Equation 13, various global optimization algorithms may be used. In some embodiments, the simulation device may use a genetic algorithm among the global optimization algorithms, and may derive an optimal parameter set within a range defined in Table 2.

TABLE 2

| | | | | Lower | Upper |
|---|---|---|---|---|---|
| Description | | Parameter | Symbol | boundary | boundary |
| Design | Dielectric | Half | hₜ | 0.1 mm | 0.5 mm |
| parameters | material | thickness | | | |
| | | Relative | ε_{r,m} | 2 | 4 |
| | | permittivity | | | |
| | Electrodes | Width | w | 0.1 mm | 2 mm |
| | | Gap | s | 0.1 mm | 2 mm |
| | | (separation) | | | |
| | | Voltage input | V₀ | 1 kV | 10 kV |

In some embodiments, the simulation device may define the objective function F based on the filtration efficiency n as in Equation 15. The objective function F may have the maximum electric field strength |E|ₘₐₓ as a constraint, as in Equation 15.

$$min F ( Ξ ) ≡ 1 - η + p \times H ( \frac{{\vert E \vert}_{max}}{σ} - 1 ) \qquad Equation 15$$

In Equation 15, p denotes a penalty constant for a constraint violation, and may be, for example, 2. H(x) denotes a step function, and may be, for example, defined as in Equation 16. If the design parameter set violates the constraint, |E|ₘₐₓ≥σ, so F=(1−η)+p, and if the design parameter set satisfies the constraint, |E|ₘₐₓ<σ, so F=(1−η). Therefore, when the genetic algorithm minimizes the objective function F, a design parameter set that violates the constraint may have a larger F value than a design parameter set that satisfies the constraint to be eliminated in the genetic algorithm.

$$H ( x ) = \{ \begin{matrix}0 for x < 0 \\ 1 for x \geq 0\end{matrix} \qquad Equation 16$$

In some embodiments, the simulation device may scale each design parameter so that a minimum value of each design parameter is 0 and a maximum value of each design parameter is 1. A scaled value ξⱼ of each design parameter Ξⱼ in a scaled design parameter set shown in Equation 17 may be defined as in Equation 18.

$$ξ = ( {\tilde{h}}_{t} , {\tilde{ε}}_{r , m} , \tilde{w} , \tilde{s} , {\tilde{V}}_{0} ) \qquad Equation 17$$

$${ξ}_{j} = \frac{{Ξ}_{j} - min ( {Ξ}_{j} )}{max ( {Ξ}_{j} ) - min ( {Ξ}_{j} )} \qquad Equation 18$$

In Equation 18, Ξⱼ denotes the j^{th} design parameter in the design parameter set.

As shown in FIG. 10, in cases that the simulation device randomly generates a plurality of parameter sets (e.g., 200 parameter sets) in an initial state (iterations=0), some parameter sets among the plurality of parameter sets may violate the constraint, so F may have a value greater than p. However, as shown in FIG. 11, FIG. 12, and FIG. 13, as the optimization algorithm proceeds through iterations, parameter sets that violate the constraint may be eliminated, and all parameter sets may satisfy the constraint, and the F value may be minimized. In other words, the filtration efficiency may be maximized. As a result of performing the optimization in the design parameter set range shown in Table 2 while fixing the design parameters related to the parallel plates, the particle parameters, the air parameters, and the vacuum permittivity shown in Table 1, an optimization result ξₒₚₜ of the scaled design parameter set was derived as (0.42, 0.79, 0.39, 0.32, 1), and an optimization result Ξₒₚₜ of the final design parameter set was derived as (0.27 mm, 3.57, 0.84 mm, 0.71 mm, 10 KV). It can be seen that the optimization result has a reduced electrode width w and an increased applied voltage V₀ compared to the design parameters shown in Table 1. The filtration efficiency based on the optimization result of the design parameter set was confirmed to be 92%. Therefore, a dielectrophoretic air filter with the same pressure drop and improved filtration efficiency can be designed compared to a dielectrophoretic air filter having the parameter set shown in Table 1.

As described above, by using the simulation method and the optimization algorithm according to an embodiment, the dielectrophoretic air filter with optimized design parameters related to the electrodes can be provided by setting the width of the electrode to 0.88 mm, the gap between two adjacent electrodes to 0.71 mm, and the magnitude of the voltage applied to each electrode to 10 kV. In some embodiments, the design parameters related to the dielectric material in the dielectrophoretic air filter can be optimized by setting the relative permittivity of the dielectric material to 3.57 and the half of the thickness of the dielectric material (i.e., the thickness of the parallel plate) to 0.27 mm.

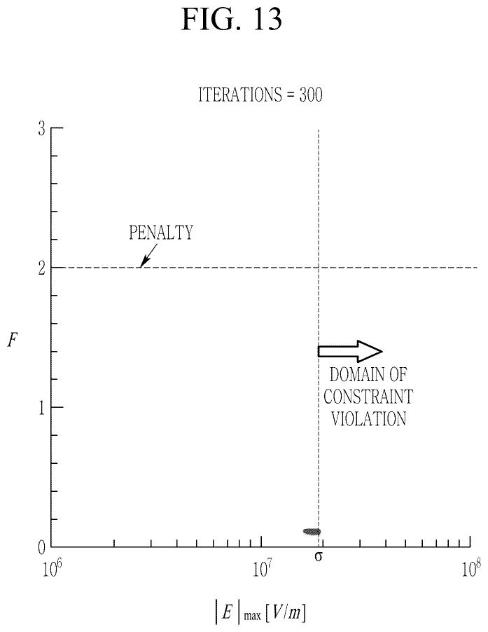

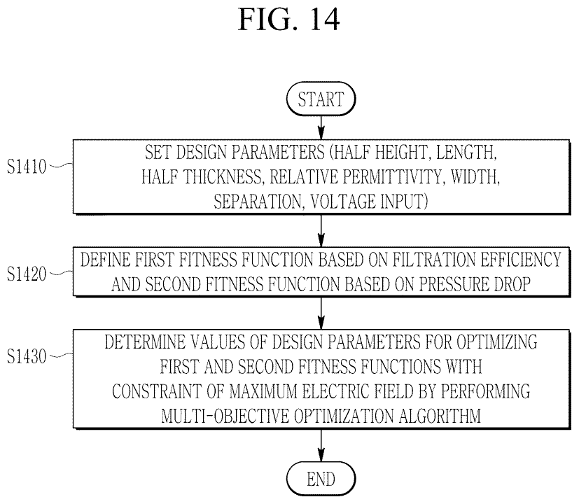

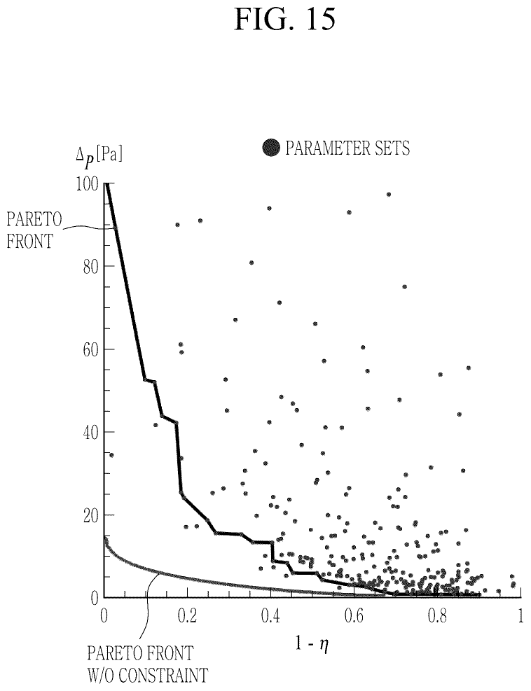

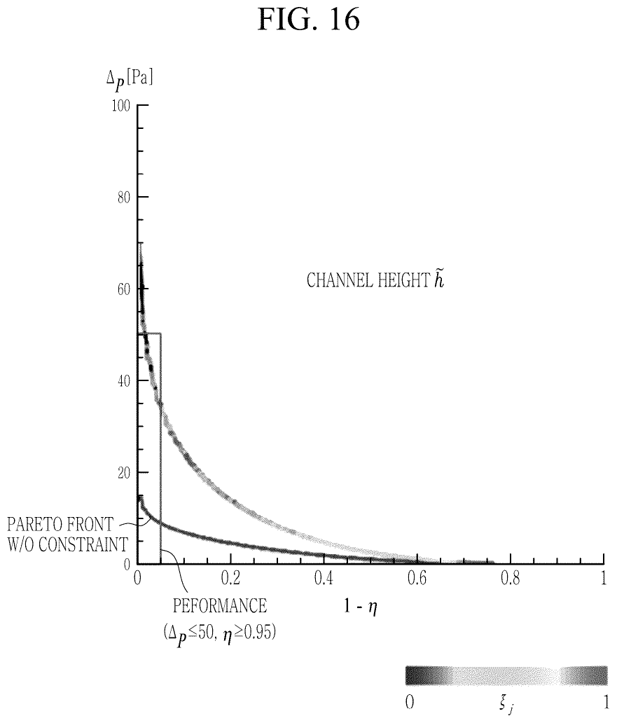

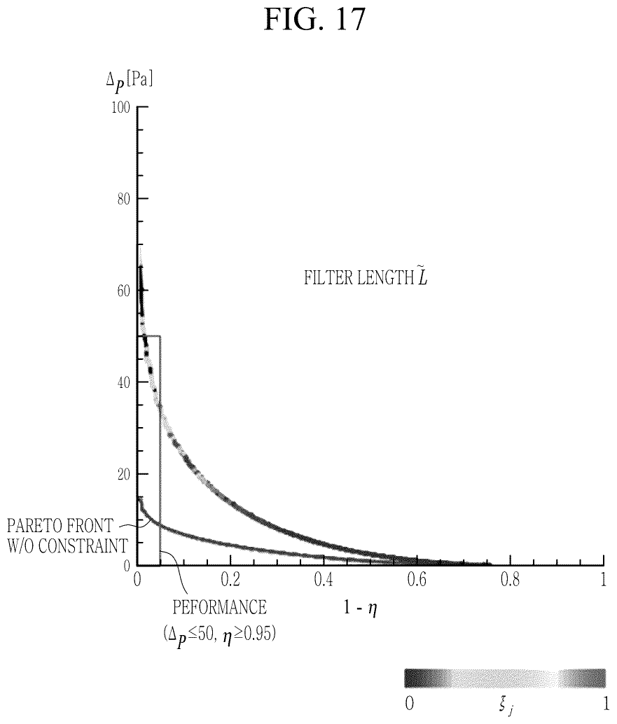

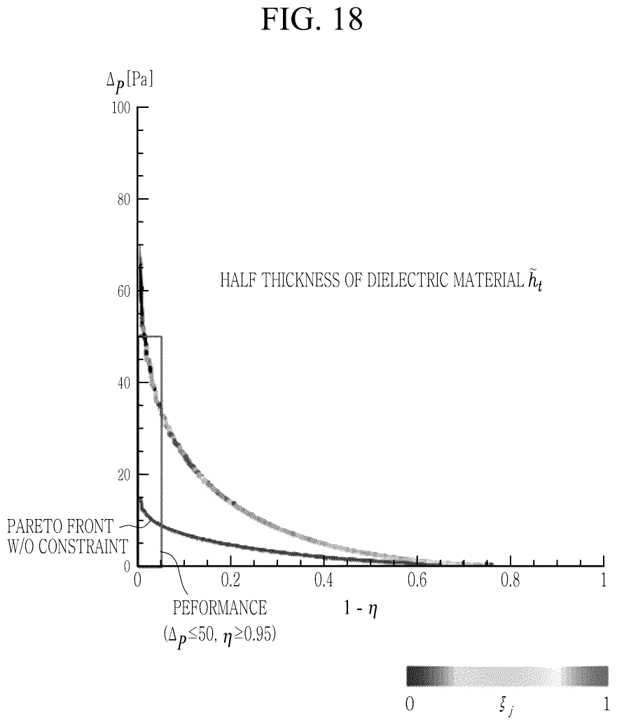

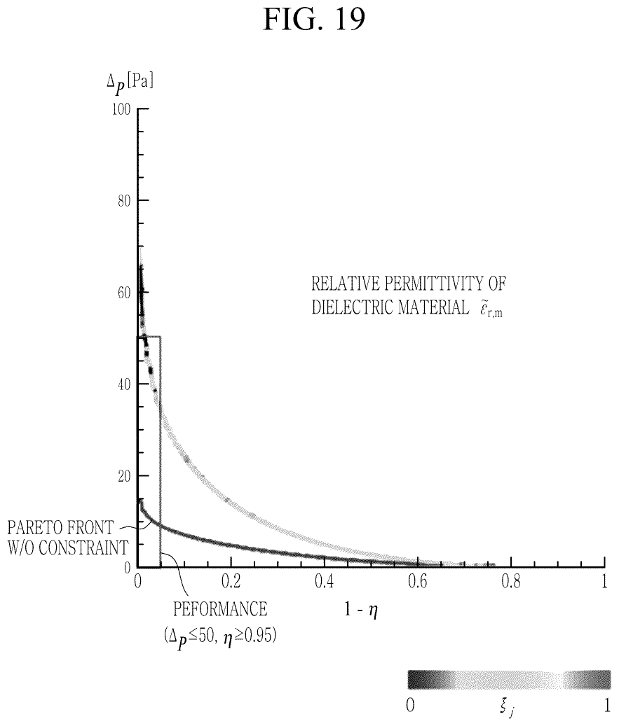

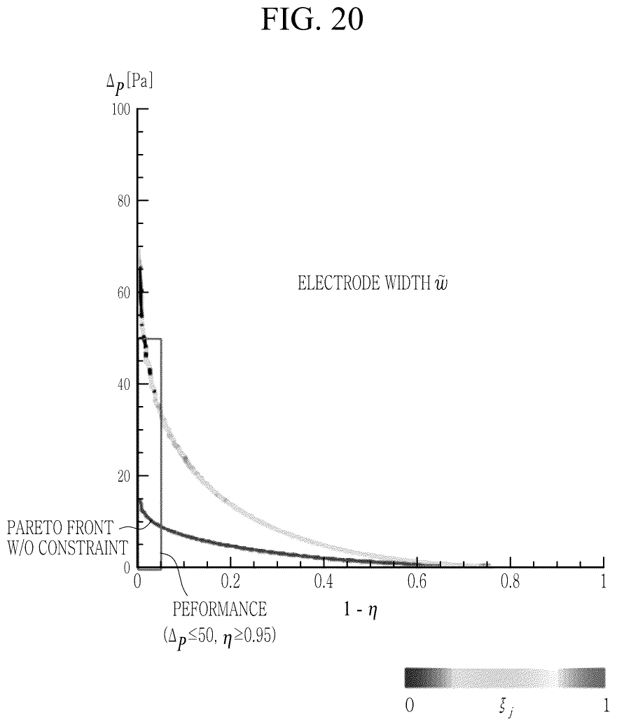

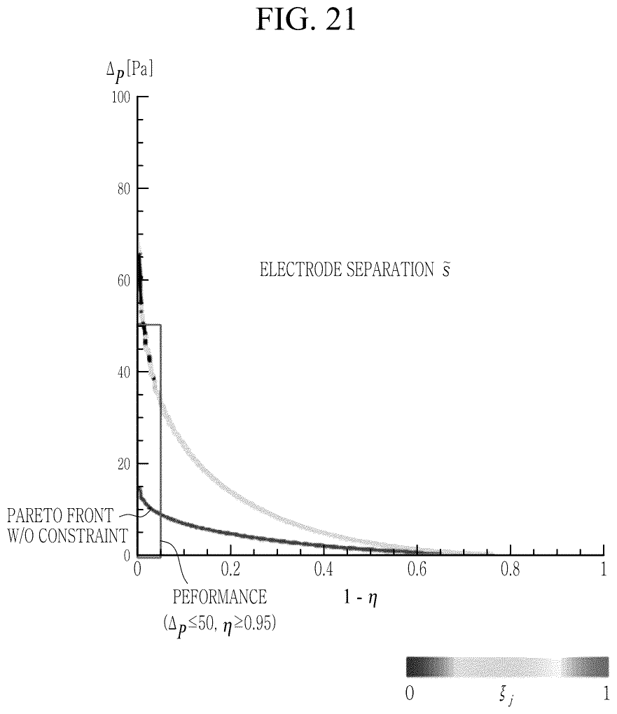

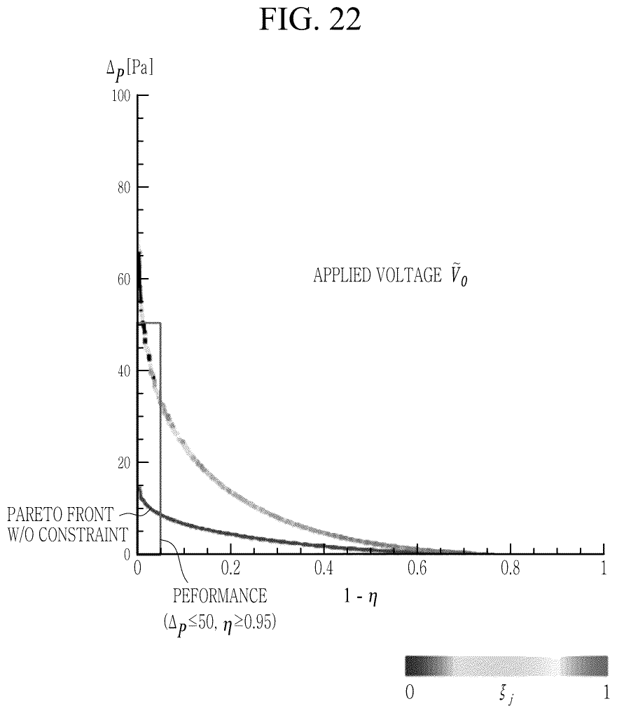

FIG. 14 is a flowchart illustrating a design method of a dielectrophoretic air filter according to an embodiment, FIG. 15 is a diagram illustrating an optimization process in an optimization algorithm according to an embodiment, FIG. 16 is a diagram illustrating an optimization of a half gap of a parallel plate in an optimization algorithm according to an embodiment, FIG. 17 is a diagram illustrating an optimization of a length of a parallel plate in an optimization algorithm according to an embodiment, FIG. 18 is a diagram illustrating an optimization of a half thickness of a dielectric material in an optimization algorithm according to an embodiment, FIG. 19 is a diagram illustrating an optimization of a relative permittivity of a dielectric material in an optimization algorithm according to an embodiment, FIG. 20 is a diagram illustrating an optimization of a width of an electrode in an optimization algorithm according to an embodiment, FIG. 21 is a diagram illustrating an optimization of a gap of an electrode in an optimization algorithm according to an embodiment, and FIG. 22 is a diagram illustrating an optimization of an applied voltage in an optimization algorithm according to an embodiment.

Referring to FIG. 14, a simulation device may set design parameters to be used for optimization among a plurality of parameters that determine performance of a dielectrophoretic air filter (S1410). The simulation device may aim to maximize a filtration efficiency of the dielectrophoretic air filter and to minimize a pressure drop of the dielectrophoretic air filter. In this case, the simulation device may optimize the design parameters related to parallel plates, a dielectric material, and electrodes (e.g., a half gap (alternatively, half height or channel height) h of the parallel plates, a length L (alternatively, filter length) of the parallel plate, a half thickness (alternatively, thickness) hₜ of the dielectric material (ht), a relative permittivity ε_{r,m} of the dielectric material, a width w of the electrode w, a gap (alternatively, separation) s between the electrodes, an applied voltage V₀).

The simulation device may define an objective function based on the filtration efficiency and the pressure drop, which are the performance of the dielectrophoretic air filter to be optimized (S1420). The simulation device may define a first objective function for maximizing the filtration efficiency based on the filtration efficiency, and may define a second objective function for minimizing the pressure drop based on the pressure drop. The simulation device may determine optimized values of the design parameters that optimize the first and second objective functions by performing an optimization algorithm (S1430).

In some embodiments, the simulation device may optimize the design parameters so that a maximum electric field strength |E|ₘₐₓ in a space between the parallel plates is equal to or smaller than a certain value σ to prevent an air discharge. The certain value σ may be, for example, 1.9×10⁷ V/m. The simulation device may optimize the design parameters by optimizing the first and second objective functions with an inequality constraint as in Equation 19.

$$\{ \begin{matrix}minimize 1 - η ( Ξ ) \\ minimize Δ p ( Ξ )\end{matrix} subject to {\vert E \vert}_{max} ( Ξ ) < σ \qquad Equation 19$$

In Equation 19, Ξ is a design parameter set to be optimized, and in some embodiments, may be given as in Equation 20. σ is a constant value for the constraint to prevent the air discharge, and may be, for example, 1.9×10⁷ V/m.

Ξ=(h,L,hₜ,ε_{r,m},w,s,V₀) Equation 20

In the dielectrophoretic air filter, in case of increasing the filtration efficiency, the pressure drop may also increase, so an optimization to increase the filtration efficiency may conflict with an optimization to decrease the pressure drop. To solve this, in some embodiments, the simulation device may use a multi-objective optimization algorithm that optimizes an objective function for increasing the filtration efficiency and an objective function for decreasing the pressure drop, and may derive an optimal parameter set within the range defined in Table 3.

TABLE 3

| | | | | Lower | Upper | |
|---|---|---|---|---|---|---|
| Description | | Parameter | Symbol | boundary | boundary | Optimization |
| Design | Parallel | Mean | ū | 1 m/s | | |
| parameters | plates | velocity | | | | |
| | (Channel) | Half gap | h | 0.25 mm | 2.5 mm | 0.46~0.73 mm |
| | | (half | | | | |
| | | height) | | | | |
| | | Length | L | 50 mm | 500 mm | 109~326 mm |
| | Dielectric | Half | hₜ | 0.1 mm | 0.5 mm | 0.13~0.19 mm |
| | material | thickness | | | | |
| | | Relative | ε_{r, m} | 2 | 4 | 2.7~3.3 |
| | | permittivity | | | | |
| | Electrodes | Width | w | 0.1 mm | 2 mm | 0.45~0.77 mm |
| | | Gap | s | 0.1 mm | 2 mm | 0.63~0.90 mm |
| | | (separation) | | | | |
| | | Voltage | V₀ | 1 kV | 10 kV | 6.3~8.8 kV |
| | | input | | | | |

In some embodiments, the simulation device may scale each design parameter so that a minimum value of each design parameter is 0 and a maximum value of each design parameter is 1. A scaled value ξⱼ of each design parameter E; in a scaled design parameter set shown in Equation 21 may be defined as in Equation 18 described above.

ξ=(\tilde{h},\tilde{L},\tilde{h}ₜ,\tilde{ε}_{r,m},\tilde{w},\tilde{s},\tilde{V}₀) Equation 21

The simulation device may randomly generate a plurality of parameter sets (e.g., 200 parameter sets) in an initial state (iterations=0), and may calculate a filtration efficiency n and a pressure drop Δp for the plurality of parameter sets. In this case, a Pareto front corresponding to a set of Pareto optimal solutions of the multi-objective optimization algorithm may be given as in FIG. 15. As the multi-objective optimization algorithm proceeds through iterations, the Pareto front of the parameter set may reach an ideal Pareto front as in FIGS. 16 to 22. FIGS. 16 to 22 are diagrams in which the parameter set corresponding to the Pareto front is separated by parameter. In FIGS. 15 to 22, the Pareto front in the case where there is no constraint is also shown for comparison.

As shown in FIGS. 16 to 22, a Pareto front of the objective function that maximizes the filtration efficiency and the objective function that minimizes the pressure drop may be derived. The simulation device may determine a parameter corresponding to the Pareto front that satisfies a filtration efficiency condition and a pressure drop condition from among the parameters corresponding to the Pareto front as an optimized parameter. The filtration efficiency condition and the pressure drop condition may be a condition required in the field where the dielectrophoretic air filter is used, and may be a condition where the filtration efficiency is 95% or more and the pressure drop is 50 Pa or less.

As shown in FIG. 16, it can be seen that in the scaled parameter h of the half gap (alternatively, channel height) h of the parallel plate among the parameter set corresponding to the Pareto front, the scaled parameter h having a value of 0.095 to 0.214 satisfies the condition that the filtration efficiency is 95% or more and the pressure drop is 50 Pa or less. In this case, the optimized half gap h of the parallel plates may be 0.46 to 0.73 mm.

As shown in FIG. 17, it can be seen that in the scaled parameter L of the length (alternatively, filter length) L of the parallel plate among the parameter set corresponding to the Pareto front, the scaled parameter L having a value of 0.131 to 0.614 satisfies the condition that the filtration efficiency is 95% or more and the pressure drop is 50 Pa or less. In this case, the optimized length L of the parallel plate may be 109 to 326 mm.

As shown in FIG. 18, it can be seen that in the scaled parameter \tilde{h}ₜ of the half thickness hₜ of the dielectric material among the parameter set corresponding to the Pareto front, the scaled parameter \tilde{h}ₜ having a value of 0.074 to 0.215 satisfies the condition that the filtration efficiency is 95% or more and the pressure drop is 50 Pa or less. In this case, the optimized half thickness hₜ of the dielectric material may be 0.13 to 0.19 mm.

As shown in FIG. 19, it can be seen that in the scaled parameter ε_{r,m} of the relative permittivity ε_{r,m} of the dielectric material among the parameter set corresponding to the Pareto front, the scaled parameter \tilde{ε}_{r,m} having a value of 0.358 to 0.626 satisfies the condition that the filtration efficiency is 95% or more and the pressure drop is 50 Pa or less. In this case, the optimized relative permittivity ε_{r,m} of the dielectric material may be 2.7 to 3.3.

As shown in FIG. 20, it can be seen that in the scaled parameter w of the width w of the electrode among the parameter set corresponding to the Pareto front, the scaled parameter w having a value of 0.187 to 0.335 satisfies the condition that the filtration efficiency is 95% or more and the pressure drop is 50 Pa or less. In this case, the optimized width w of the electrode may be 0.45 to 0.77 mm.

As shown in FIG. 21, it can be seen that in the scaled parameter \tilde{s} of the gap (alternatively, separation) s between the electrodes among the parameter set corresponding to the Pareto front, the scaled parameter \tilde{s} having a value of 0.227 to 0.442 satisfies the condition that the filtration efficiency is 95% or more and the pressure drop is 50 Pa or less. In this case, the optimized gap s between the electrodes may be 0.63 to 0.90 mm.

As shown in FIG. 22, it can be seen that in the scaled parameter \tilde{V}₀ of the applied voltage V₀ among the parameter set corresponding to the Pareto front, the scaled parameter \tilde{V}₀ having a value of 0.590 to 0.869 satisfies the condition that the filtration efficiency is 95% or more and the pressure drop is 50 Pa or less. In this case, the optimized applied voltage V₀ may be 6.3 to 8.8 kV.

As described above, by using the simulation method and the optimization algorithm according to an embodiment, a dielectrophoretic air filter with optimized design parameters related to the electrodes may be provided by selecting the width of the electrode among from 0.45 to 0.77 mm, selecting the gap between two adjacent electrodes among from 0.63 to 0.90 mm, and selecting the magnitude of the voltage applied to each electrode among from 6.3 to 8.8 kV. In some embodiments, the design parameters related to the dielectric material in the dielectrophoretic air filter may be optimized by selecting the relative permittivity of the dielectric material among from 2.7 to 3.3, and selecting the half of the thickness of the dielectric material (i.e., the thickness of the parallel plate) among from 0.13 to 0.19 mm. In some embodiments, the design parameters related to the parallel plates may be optimized by selecting the half of the gap between two parallel plates in the dielectrophoretic air filter among from 0.46 to 0.73 mm, and selecting the length of the parallel plate among from 109 to 326 mm. In some embodiments, a manufacturing method of a dielectrophoretic air filter with at least some of the optimized design parameters above obtained by using the simulation method and the optimization algorithm above is provided.

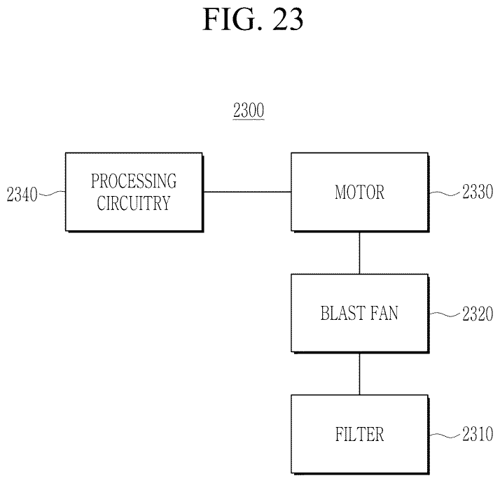

FIG. 23 is a block diagram illustrating an air filtration apparatus according to an embodiment.

Referring to FIG. 23, an air filtration apparatus 2300 may include a filter 2310, a blower fan 2320, a motor 2330, and a processing circuitry 2340.

The filter 2310 may filter air, and may include a dielectrophoretic air filter described with reference to FIGS. 1 to 22. The blower fan 2320 may form an airflow so that the air passes through the filter 2310, and the motor 2330 may drive the blower fan 2320. The processing circuitry 2340 may control an operation of the motor 2330.

In some embodiments, the simulation method or the design method described above may be implemented as a method implemented in a computer, or may be implemented as a non-transitory computer-readable medium on which computer-executable instructions are stored. In some embodiments, when executed by the processing circuit, the computer-readable instructions may perform the simulation method or the design method.

Meanwhile, embodiments are not only implemented through the apparatus and/or method described so far, but may also be implemented through a program that realizes a function corresponding to the configuration of the embodiments or a recording medium on which the program is recorded, and such implementation can be easily implemented by a person skilled in the art of the present disclosure from the disclosure of the embodiments. For example, the method according to the embodiments (e.g., simulation method or design method) may be implemented in the form of a program instruction that can be executed through various computer means, and may be recorded on a computer-readable medium. The computer-readable medium may include program instructions, data files, data structures, and the like singly or in combination. The computer-readable recording medium may include a hardware device configured to store and execute program instructions. For example, the computer-readable recording medium may include a magnetic medium such as a hard disk, a floppy disk, or a magnetic tape, an optical medium such as a CD-ROM or a DVD, or a magneto-optical medium such as a floptical disk, a ROM, a RAM, or a flash memory. The program instructions may include a machine language code created by a compiler, or a high-level language code that can be executed by a computer through an interpreter.

While the inventive concepts have been described in connection with what is presently considered to be practical embodiments, it is to be understood that the inventive concepts are not limited to the disclosed embodiments. On the contrary, it is intended to cover various modifications and equivalent arrangements included within the spirit and scope of the appended claims.

What is claimed is:

1. A dielectrophoretic air filter comprising:
a plurality of parallel plates, which are stacked in a first direction and are made of a dielectric material; and
a plurality of electrodes, which extend in a second direction inside each parallel plate of the plurality of parallel plates and are arranged in a third direction,
wherein a width of each electrode of the plurality of electrodes is 0.45 to 0.77 millimeters (mm),
wherein a gap between two adjacent electrodes among the plurality of electrodes is 0.63 to 0.90 mm, and
wherein a magnitude of a voltage applied to each electrode is 6.3 to 8.8 kilovolts (kV).

2. The dielectrophoretic air filter of claim 1, wherein a relative permittivity of the dielectric material is 2.7 to 3.3, and
wherein a half of a thickness of each parallel plate is 0.13 to 0.19 mm.

3. The dielectrophoretic air filter of claim 1, wherein a half of a gap between two adjacent parallel plates among the plurality of parallel plates is 0.46 to 0.73 mm, and
wherein a length of each parallel plate is 109 to 326 mm.

4. The dielectrophoretic air filter of claim 3, wherein a relative permittivity of the dielectric material is 2.7 to 3.3, and
wherein a half of a thickness of each parallel plate is 0.13 to 0.19 mm.

5. The dielectrophoretic air filter of claim 1, wherein a filtration efficiency of the dielectrophoretic air filter is 95% or more, and a pressure drop of the dielectrophoretic air filter is 50 pascals (Pa) or less.

6. The dielectrophoretic air filter of claim 1, wherein a maximum electric field strength in a space between two adjacent parallel plates among the plurality of parallel plates is 1.9×10⁷ volts per meter (V/m) or less.

7. The dielectrophoretic air filter of claim 1, wherein first voltages of opposite polarities are applied to the two adjacent electrodes among the plurality of electrodes, and
wherein second voltages of opposite polarities are applied to two electrodes facing each other in two adjacent parallel plates among the plurality of parallel plates.

8. The dielectrophoretic air filter of claim 1, wherein the first direction, the second direction, and the third direction are substantially orthogonal to each other.

9. An air filtration apparatus comprising the dielectrophoretic air filter according to claim 1.

10. A design method, performed by a computing device, of a dielectrophoretic air filter comprising a plurality of parallel plates made of a dielectric material and a plurality of electrodes arranged inside each parallel plate of the plurality of parallel plates, the method comprising:
setting a plurality of design parameters among a plurality of parameters, which determine performance of the dielectrophoretic air filter; and
determining optimized values of the plurality of design parameters by performing an optimization algorithm, which optimizes the performance of the dielectrophoretic air filter.

11. The design method of claim 10, wherein the performance comprises a filtration efficiency of the dielectrophoretic air filter.

12. The design method of claim 11, wherein the optimization algorithm optimizes an objective function defined based on the filtration efficiency.

13. The design method of claim 12, wherein the objective function has a maximum electric field strength in a space between two adjacent parallel plates among the plurality of parallel plates as a constraint.

14. The design method of claim 11, wherein the plurality of design parameters comprise at least one of a width of each electrode, a gap between two adjacent electrodes among the plurality of electrodes, a magnitude of a voltage applied to each electrode, a relative permittivity of the dielectric material, or a thickness of each parallel plate.

15. The design method of claim 11, wherein the performance further comprises a pressure drop of the dielectrophoretic air filter.

16. The design method of claim 15, wherein the optimization algorithm is a multi-objective optimization algorithm, and
wherein the multi-objective optimization algorithm optimizes a first objective function defined based on the filtration efficiency and a second objective function defined based on the pressure drop.

17. The design method of claim 16, wherein the first objective function and the second objective function have a maximum electric field strength in a space between two adjacent parallel plates among the plurality of parallel plates as a constraint.

18. The design method of claim 15, wherein the plurality of design parameters comprise at least one of a width of each electrode, a gap between two adjacent electrodes among the plurality of electrodes, a magnitude of a voltage applied to each electrode, a relative permittivity of the dielectric material, a thickness of each parallel plate, a length of each parallel plate, or a gap between two adjacent parallel plates among the plurality of parallel plates.

19. The design method of claim 11, wherein the determining the optimized values comprises calculating the filtration efficiency by simulating a behavior of particles in the dielectrophoretic air filter.

20. The design method of claim 19, wherein the simulating of the behavior comprises:
calculating a velocity of a target particle in the dielectrophoretic air filter, based on a relationship among an aerodynamic drag force, a dielectrophoretic force, a gravitational force and the velocity;
updating a position of the target particle based on the velocity;
determining whether the target particle has been captured by the dielectrophoretic air filter or has penetrated the dielectrophoretic air filter, based on the updated position of the target particle;
updating a number of particles captured by the dielectrophoretic air filter and a number of particles having penetrated the dielectrophoretic air filter among a plurality of particles input to the dielectrophoretic air filter; and
calculating the filtration efficiency based on a total number of the plurality of particles input to the dielectrophoretic air filter and the number of particles captured by the dielectrophoretic air filter.
